(19) United States
(12) Patent Application Publication
(10) Pub. No.: US 2025/0216438 A1
(43) Pub. Date: Jul. 3, 2025

(54) INSPECTION DEVICE, INSPECTION METHOD, AND PROGRAM

(71) Applicants: Kabushiki Kaisha Toshiba, Tokyo (JP); Toshiba Electronic Devices & Storage Corporation, Tokyo (JP)

(72) Inventors: Ryusei MASUDA, Tokyo (JP); Hitoshi IMI, Yokohama (JP)

(73) Assignees: Kabushiki Kaisha Toshiba, Tokyo (JP); Toshiba Electronic Devices & Storage Corporation, Tokyo (JP)

(21) Appl. No.: 18/826,381

(22) Filed: Sep. 6, 2024

(30) Foreign Application Priority Data
Dec. 27, 2023 (JP) 2023-220508

(51) Int. Cl. G01R 31/26

(52) U.S. Cl. CPC G01R 31/2621; G01R 31/2601

(57) ABSTRACT

An inspection device for performing operation inspection of a circuit including a transistor may include, but is not limited to, a standard calculating circuitry and a standard determining circuitry. The standard calculating circuitry is configured to calculate an electrical standard of the transistor on the basis of information on specifications of the transistor. The standard determining circuitry is configured to determine whether an inspection data group including temporal data of a value of current flowing in the transistor in a predetermined time range and of a value of voltage applied to the transistor satisfies the electrical standard and to output data which is determined not to satisfy the electrical standard in the inspection data group.

### CROSS-REFERENCE TO RELATED APPLICATION

This application is based upon and claims the benefit of priority from Japanese Patent Application No. 2023-220508, filed on Dec. 27, 2023; the entire contents of which are incorporated herein by reference.

### FIELD

Embodiments described herein relate generally to an inspection device, an inspection method, and a program.

### BACKGROUND

For design of circuits including transistors, it can be desirable to inspect whether the circuits can operate without causing breakage, deterioration, or the like of the transistor. An example of such inspections may be, but is not limited to, a method of comparing a double logarithmic graph, indicating a safe operating area (SOA), an electrical standard, described in a data sheet of a transistor, with data of a value of current flowing in the transistor and a value of voltage applied to the transistor which are acquired by simulation or the like and determining whether the data is included in the safe operating area. However, in case that an inspection operator manually performs such inspection method, a large workload may be required. On the other hand, for example, the operator inputting conditions of the safe operating area to computers and the inspection method being automatically performed can also be considered. However, in this case, since the operator takes charge of setting conditions of the safe operating area, there may be raised a risk of inaccuracy of inspection. Related art is disclosed in Japanese Unexamined Patent Application, First Publication No. 2002-175345.

### BRIEF DESCRIPTION OF THE DRAWINGS

FIG. 1 is a block diagram illustrating a configuration of an inspection device according to an embodiment.

FIG. 2 is a diagram illustrating an example of a circuit of which operation inspection is performed by the inspection device according to the embodiment.

FIG. 3 is a diagram illustrating an example of an inspection data group according to the embodiment as a time waveform.

FIG. 4 is a diagram illustrating an example of a double logarithmic graph representing a safe operating area of a transistor.

FIG. 5 is a diagram illustrating an example of a graph representing a change of a transient thermal resistance with respect to a pulse width of a pulse current applied to the transistor.

FIG. 6 is a diagram illustrating an example of a double logarithmic graph of a safe operating area corresponding to a first classification prepared by a standard calculating circuitry according to the embodiment.

FIG. 7 is a diagram illustrating an example of a double logarithmic graph of a safe operating area corresponding to a second classification prepared by the standard calculating circuitry according to the embodiment.

FIG. 8 is a diagram illustrating an example of a double logarithmic graph of a safe operating area corresponding to a third classification prepared by the standard calculating circuitry according to the embodiment.

FIG. 9 is a diagram illustrating an example of a graph representing a change of a permissible loss with respect to a case temperature of the transistor.

FIG. 10 is a diagram illustrating an example in which the double logarithmic graph of the safe operating area corresponding to the second classification is adjusted according to the embodiment.

FIG. 11 is a diagram illustrating an example in which sampling data determined to be in the first classification is plotted on the double logarithmic graph of the safe operating area of the first classification according to the embodiment.

FIG. 12 is a diagram illustrating an example in which sampling data determined to be in the second classification is plotted on the double logarithmic graph of the safe operating area of the second classification according to the embodiment.

FIG. 13 is a diagram illustrating an example in which sampling data determined to be in the third classification is plotted on the double logarithmic graph of the safe operating area of the third classification according to the embodiment.

FIG. 14 is a diagram illustrating an example in which sampling data determined to be in the second classification is plotted on the adjusted double logarithmic graph of the safe operating area of the second classification according to the embodiment.

FIG. 15 is a diagram illustrating an example of a time waveform that is generated by a waveform generating circuitry according to the embodiment.

FIG. 16 is a flowchart illustrating an example of a calculation flow that is performed by a calculation circuitry according to the embodiment.

FIG. 17 is a flowchart illustrating an example of a process flow that is performed by a data determining circuitry according to the embodiment.

FIG. 18 is a flowchart illustrating an example of a process flow that is performed by a standard calculating circuitry according to the embodiment.

FIG. 19 is a flowchart illustrating an example of a process flow that is performed by a standard determining circuitry according to the embodiment.

FIG. 20 is a flowchart illustrating an example of a process flow that is performed by the waveform generating circuitry according to the embodiment.

### DETAILED DESCRIPTION

In some embodiments, an inspection device for performing operation inspection of a circuit including a transistor may include, but is not limited to, a standard calculating circuitry and a standard determining circuitry. The standard calculating circuitry is configured to calculate an electrical standard of the transistor on the basis of information on specifications of the transistor. The standard determining circuitry is configured to determine whether an inspection data group including temporal data of a value of current flowing in the transistor in a predetermined time range and of a value of voltage applied to the transistor satisfies the electrical standard and to output data which is determined not to satisfy the electrical standard in the inspection data group.

In some embodiments, an inspection method of performing operation inspection of a circuit including a transistor may include, but is not limited to, calculating an electrical standard of the transistor on the basis of information on specifications of the transistor; determining whether an inspection data group including temporal data of a value of current flowing in the transistor in a predetermined time range and of a value of voltage applied to the transistor satisfies the electrical standard; and outputting data which is determined not to satisfy the electrical standard in the inspection data group.

In some embodiments, a non-transitory computer readable storage medium that stores a computer-executable program that causes, when executed by a computer, the computer to perform the inspection method. The inspection method may include, but is not limited to, calculating an electrical standard of the transistor on the basis of information on specifications of the transistor; determining whether an inspection data group including temporal data of a value of current flowing in the transistor in a predetermined time range and of a value of voltage applied to the transistor satisfies the electrical standard; and outputting data which is determined not to satisfy the electrical standard in the inspection data group.

Hereinafter, an inspection device, an inspection method, and a program according to an embodiment will be described with reference to the accompanying drawings.

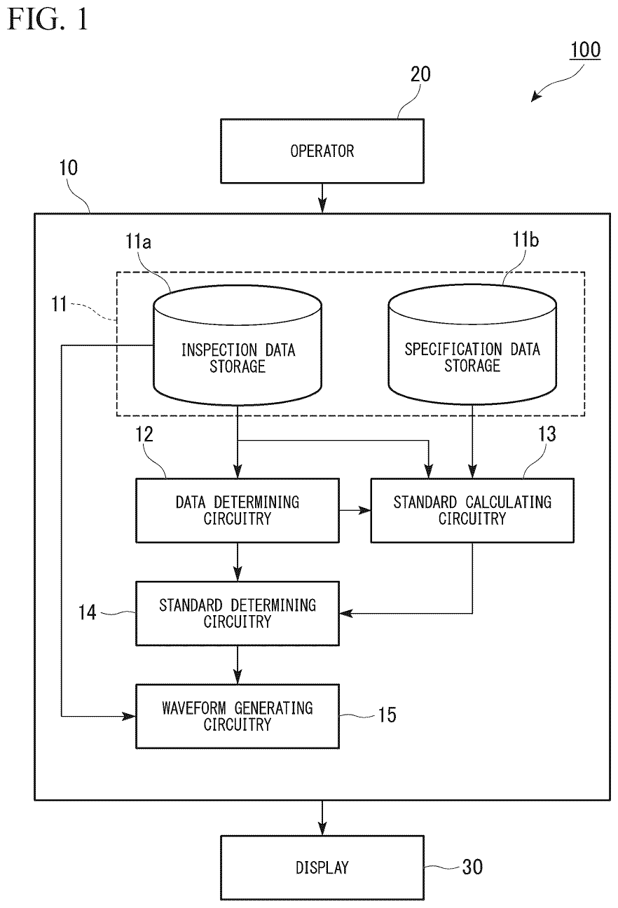

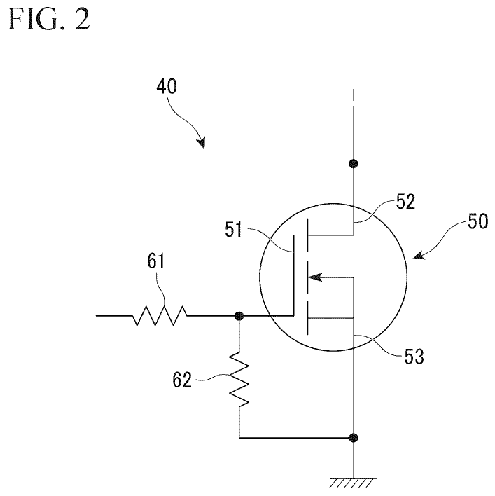

FIG. 1 is a block diagram illustrating a configuration of an inspection device 100 according to an embodiment. The inspection device 100 according to the embodiment illustrated in FIG. 1 is a device that performs operation inspection of a circuit 40 including a transistor 50. FIG. 2 is a diagram illustrating an example of the circuit 40 of which operation inspection is performed by the inspection device 100. As illustrated in FIG. 2, the circuit 40 includes a transistor 50. In the example illustrated in FIG. 2, the transistor 50 is a field effect transistor (FET) including a gate 51, a drain 52, and a source 53. In the circuit 40, a resistor 61 is connected to the gate 51. A gate voltage is applied to the gate 51 via the resistor 61. A resistor 62 connecting the gate 51 and the source 53 is provided in the circuit 40. The source 53 in the circuit 40 is grounded.

The inspection device 100 is, for example, a computer. A program for causing the inspection device 100 which is a computer to perform an inspection method according to this embodiment is installed in the inspection device 100. As illustrated in FIG. 1, the inspection device 100 includes a calculation circuitry 10, an operator 20, and a display 30. The operator 20 is a part that allows an operator to operate the inspection device 100. The operator 20 includes, for example, a keyboard and a mouse. An operator can input various types of data to the calculation circuitry 10 and cause the calculation circuitry 10 to start its calculation by operating the operator 20. The display 30 is a part that can display a calculation result from the calculation circuitry 10. The display 30 is, for example, a display. When the inspection device 100 is a smart device such as a smartphone or a tablet terminal, a screen of the smart device may serve as the operator 20 and the display 30.

The calculation circuitry 10 is, for example, a processor such as a central processing unit (CPU) in which a program for executing the inspection method according to the embodiment is installed. The calculation circuitry 10 executes the inspection method according to the embodiment of performing operation inspection of the circuit 40. The calculation circuitry 10 includes a storage 11, a data determining circuitry 12, a standard calculating circuitry 13, a standard determining circuitry 14, and a waveform generating circuitry 15.

The storage 11 is a part that stores various types of data. The storage 11 is realized, for example, by a storage medium such as a random access memory (RAM), a read only memory (ROM), a hard disk drive (HDD), or a flash memory. Data input via the operator 20 by an operator, data of a file read via the operator 20 by an operator, and the like are stored in the storage 11.

The storage 11 includes an inspection data storage 11a and a specification data storage 11b. The inspection data storage 11a is a part that stores an inspection data group DG including temporal data of a value of current flowing in the transistor 50 in a predetermined time range TR and a value of voltage applied to the transistor 50 when the circuit 40 operates. The inspection data group DG in this embodiment is a data group acquired through simulation. A method of acquiring the inspection data group DG through simulation is not particularly limited, and all existing methods can be employed. A plurality of pieces of data included in the inspection data group DG are sampling data Sd acquired in a predetermined sampling period. The sampling period is, for example, 0.1 microseconds or more. A value of voltage of the sampling data Sd in this embodiment is a value of a voltage applied between the drain 52 and the source 53, that is, a drain-source voltage V_{ds}. A value of current of the sampling data Sd in this embodiment is a value of a current flowing from the drain 52 to the source 53, that is, a drain current Ia.

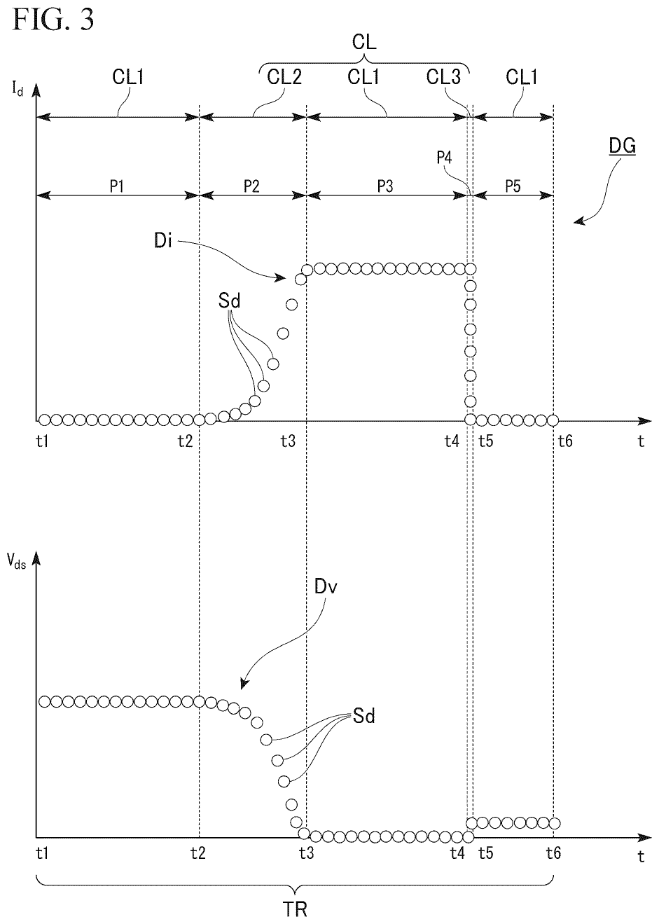

FIG. 3 is a diagram illustrating an example of the inspection data group DG as a time waveform. In the example illustrated in FIG. 3, the inspection data group DG including a value of the drain current I_{d} and a value of the drain-source voltage V_{ds} of the transistor 50 in a predetermined time range TR from time t1 to time t6 is illustrated. The upper graph of FIG. 3 is a graph representing a change of the drain current I_{d} with respect to time t. The lower graph of FIG. 3 is a graph representing a change of the drain-source voltage V_{ds} with respect to time t. In the upper graph of FIG. 3, the horizontal axis represents time t, and the vertical axis represents the drain current Ia. In the lower graph of FIG. 3, the horizontal axis represents time t, and the vertical axis represents the drain-source voltage V_{ds}. The inspection data group DG includes current data Di and voltage data Dv. Each of the current data Di and the voltage data Dv includes a plurality of pieces of sampling data Sd.

In the example of the inspection data group DG illustrated in FIG. 3, the time range TR includes a first section P1, a second section P2, a third section P3, a fourth section P4, and a fifth section P5. The first section P1, the second section P2, the third section P3, the fourth section P4, and the fifth section P5 are provided to be temporally continuous in that order. The first section P1 and the fifth section P5 are OFF sections in which the transistor 50 is in an OFF state. The second section P2 is a turning-on section in which the transistor 50 is switched from the OFF state to an ON state. The third section P3 is an ON section in which the transistor 50 is in the ON state. The fourth section P4 is a turning-off section in which the transistor 50 is switched from the ON state to the OFF state. The first section P1 is a section between time t1 and time t2. The second section P2 is a section between time t2 and time t3. The third section P3 is a section between time t3 and time t4. The fourth section P4 is a section between time 54 and time t5. The fifth section P5 is a section between time t5 and time t6. A time width of the second section P2 which is the turning-on section is larger than the time width of the fourth section P4 which is the turning-off section.

The specification data storage 11b is a part in which information on specifications of the transistor 50 is stored. The information on the specifications of the transistor 50 includes numerical values of a specification table in which various numerical values indicating the specifications of the transistor 50 are described and numerical values which are read from a graph representing the specifications of the transistor 50. The graph representing the specifications of the transistor 50 includes a graph representing a safe operating area (SOA) 70 of the transistor 50 and a graph representing a change of a transient thermal resistance rₜₕ with respect to a pulse width tw of a pulse current applied to the transistor 50.

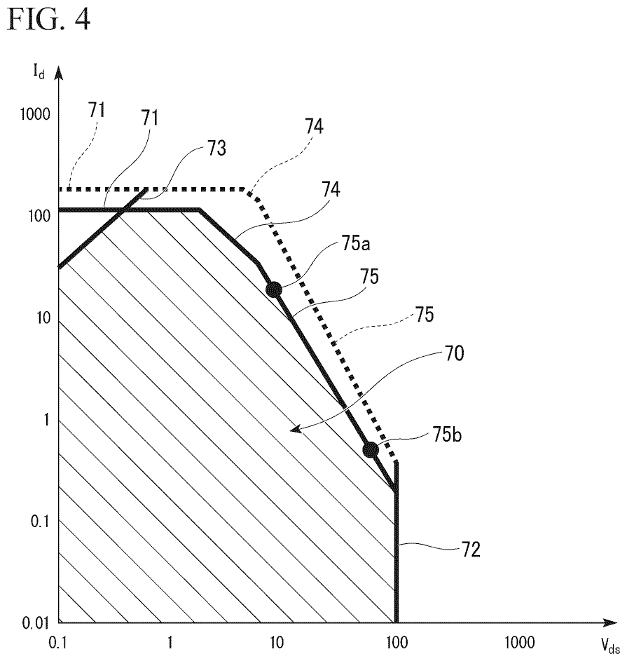

FIG. 4 is a diagram illustrating an example of a double logarithmic graph representing the safe operating area 70 of the transistor 50. In FIG. 4, the horizontal axis presents the drain-source voltage V_{ds}, and the vertical axis represents the drain current I_{d}. The safe operating area 70 is an electrical standard of the transistor 50 indicating a range of the drain current I_{d} and a range of the drain-source voltage V_{ds} in which the transistor 50 can be safely used without causing breakage or deterioration thereof. The double logarithmic graph representing the safe operating area 70 is described in a data sheet indicating the specifications of the transistor 50. The safe operating area 70 illustrated in FIG. 4 is an area that is surrounded by a current limit area 71, a voltage limit area 72, an on-resistance limit area 73, a thermal limit area 74, and a secondary breakdown area 75, that is, a hatched area in FIG. 4. When a point determined by the value of the drain current I_{d} and the value of the drain-source voltage Vas of the transistor 50 when the circuit 40 operates is plotted on the graph in FIG. 4 and the plotted point is in the safe operating area 70, the circuit 40 can operate without causing breakage or deterioration of the transistor 50.

The current limit area 71 is an area that is determined on the basis of a rated value of the drain current Ia. That is, the value of the drain current I_{d} indicated by an area line of the current limit area 71 in FIG. 4 is the rated value of the drain current Ia. The voltage limit area 72 is an area that is determined on the basis of a rated value of the drain-source voltage V_{ds}. That is, the value of the drain-source voltage V_{ds} indicated by an area line of the voltage limit area 72 in FIG. 4 is the rated value of the drain-source voltage V_{ds}.

The on-resistance limit area 73 is an area that is determined on the basis of a maximum value of an on-resistance of the transistor 50. The on-resistance of the transistor 50 is a resistance value between the drain 52 and the source 53 when a voltage equal to or greater than a threshold value is applied to the gate 51 of the transistor 50 and the transistor 50 is turned on. The thermal limit area 74 is an area that is determined on the basis of a permissible loss P_{d} of the transistor 50. The permissible loss P_{d} is a maximum power consumption at which a temperature at which performance of the transistor 50 can be maintained is not exceeded and corresponds to a rated power of the transistor 50. The thermal limit area 74 is set to a range in which breakage of the transistor 50 due to heat can be curbed.

The secondary breakdown area 75 is an area that is determined on the basis of a secondary breakdown caused in the transistor 50. The secondary breakdown caused in the transistor 50 is a phenomenon in which a current is concentrated on a channel of the transistor 50 due to a decrease in channel resistance based on an increase in temperature of the transistor 50. More specifically, when the temperature of the transistor 50 increases, the channel resistance decreases with a decrease in a threshold voltage of the gate 51, and a current is concentrated on the channel with the decreased resistance, causing the secondary breakdown. When the secondary breakdown is caused and a current is concentrated on the channel, the temperature of the transistor 50 further increases and the threshold voltage of the gate 51 decreases further. Accordingly, a current is further concentrated on the channel and there is concern about breakage of the transistor 50.

Area lines indicated by solid lines in FIG. 4 are, for example, lines indicating areas when a direct current flows in the transistor 50. The safe operating area 70 changes depending on whether the current flowing in the transistor 50 is a direct current or a pulse current. The safe operating area 70 also changes depending on a pulse width tw of a pulse current flowing in the transistor 50. The area lines of the current limit area 71, the thermal limit area 74, and the secondary breakdown area 75 indicated by dotted lines in FIG. 4 are lines indicating an area when a pulse current flows in the transistor 50. In FIG. 4, the safe operating area 70 when a pulse current flows in the transistor 50 is an area that is surrounded by the current limit area 71, the thermal limit area 74, and the secondary breakdown area 75 indicated by the dotted lines and the voltage limit area 72 and the on-resistance limit area 73 indicated by the solid lines. It can be seen from FIG. 4 that the range of the safe operating area 70 changes between when a direct current flows in the transistor 50 and when a pulse current flows in the transistor 50. The safe operating area 70 when a direct current flows in the transistor 50 is narrower than the safe operating area 70 when a pulse current flows in the transistor 50. The voltage limit area 72 and the on-resistance limit area 73 do not change, for example, depending on a current flowing in the transistor 50.

In the double logarithmic graph representing the safe operating area 70 described in a data sheet indicating the specifications of the transistor 50, the safe operating area 70 when a direct current flows in the transistor 50 and the safe operating area 70 when a pulse current flows in the transistor 50 are illustrated. As the safe operating area 70 when a pulse current flows in the transistor 50, a plurality of safe operating areas 70 with different pulse widths tw are illustrated in the double logarithmic graph representing the safe operating area 70 of the transistor 50. The plurality of safe operating areas 70 when a pulse current flows in the transistor 50 include, for example, safe operating areas 70 when the pulse width tw is 10 ms, 1 ms, 100 μs, and 10 μs.

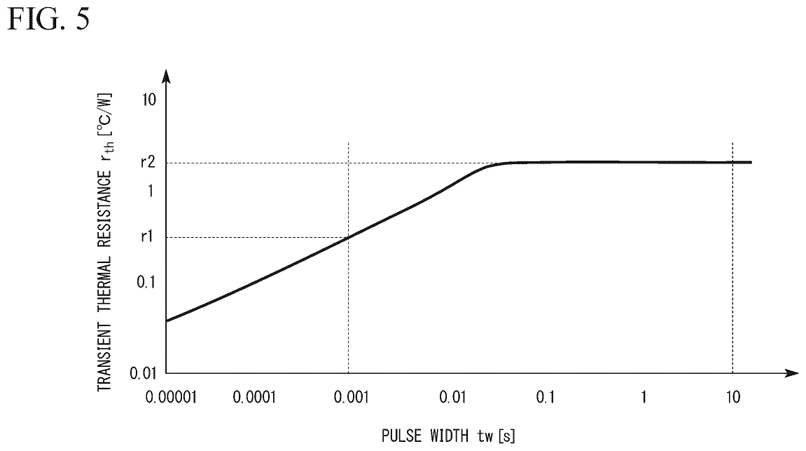

FIG. 5 is a diagram illustrating an example of a graph representing a change of a transient thermal resistance rₜₕ with respect to the pulse width tw of a pulse current applied to the transistor 50. The graph illustrated in FIG. 5 is a double logarithmic graph. In FIG. 5, the horizontal axis represents a pulse width tw [sec], and the vertical axis represents a transient thermal resistance rₜₕ [° C./W]. The transient thermal resistance rₜₕ is a thermal resistance in a time range in which there is an influence of a thermal capacity. The transient thermal resistance rₜₕ changes, for example, according to a duty ratio of a pulse current applied to the transistor 50.

In the specification data storage 11b, a rated value of the drain current I_{d} flowing in the transistor 50, a rated value of the drain-source voltage V_{ds} applied to the transistor 50, a maximum value of an on-resistance of the transistor 50, a channel temperature T_{ch} of the transistor 50, and a case temperature T_{c} of the transistor 50 are stored as information on the specifications of the transistor 50. The rated value of the drain current I_{d} flowing in the transistor 50, the rated value of the drain-source voltage V_{ds} applied to the transistor 50, the maximum value of the on-resistance of the transistor 50, the channel temperature T_{ch} of the transistor 50, and the case temperature T_{c} of the transistor 50 are, for example, numerical values that are read from the specification table of the transistor 50.

The rated value of the drain current I_{d} stored in the specification data storage 11b includes a rated value when the drain current I_{d} flowing in the transistor 50 is a direct current and a rated value when the drain current I_{d} flowing in the transistor 50 is a pulse current. The rated value when the drain current I_{d} flowing in the transistor 50 is a pulse current may be provided for each pulse current with a plurality of pulse widths tw. For example, when the rated value of the drain current I_{d} is not described in the specification table, the rated value may be read from the double logarithmic graph indicating the safe operating area 70 of the transistor 50 illustrated in FIG. 4. The case temperature T_{c} is a temperature of a case of the transistor 50. As the case temperature T_{c}, for example, a standard case temperature T_{c1} described in the specifications or the like of the transistor 50 and a maximum value of the case temperature T_{c} assumed to be reached with an increase in temperature of the transistor 50 are stored in the specification data storage 11b. The case temperature T_{c1} is, for example, 25° C. An ambient temperature Tₐ of the transistor 50 instead of the case temperature T_{c} may be stored in the specification data storage 11b.

Values of the transient thermal resistance rₜₕ corresponding to the plurality of pulse widths tw are stored in the specification data storage 11b. The values of the transient thermal resistance rₜₕ are read from the graph representing a change of the transient thermal resistance rₜₕ with respect to the pulse width tw illustrated in FIG. 5. For example, in FIG. 5, the transient thermal resistance rₜₕ when a pulse width with a pulse width tw of 0.001 seconds flows in the transistor 50 has a value r1. The value of the transient thermal resistance rₜₕ corresponding to a direct current is stored in the specification data storage 11b. The value of the transient thermal resistance rₜₕ corresponding to a direct current is also read from the graph representing a change of the transient thermal resistance rₜₕ with respect to the pulse width tw illustrated in FIG. 5. Specifically, the value of the transient thermal resistance rₜₕ when the pulse width tw is equal to or larger than a predetermined magnitude and thus the value of the transient thermal resistance rₜₕ does not change can be read as the value of the transient thermal resistance rₜₕ corresponding to a direct current. In FIG. 5, the transient thermal resistance rₜₕ is constant when the pulse width tw is equal to or greater than 0.1 seconds. For example, a value r2 of the transient thermal resistance rₜₕ when the pulse width tw is 10 seconds in FIG. 5 can be used as the value of the transient thermal resistance rₜₕ corresponding to a direct current. The value r2 is, for example, greater than the value r1.

The values of the drain current I_{d} and the values of the drain-source voltage V_{ds} at two arbitrary points on the area line indicating the secondary breakdown area 75 are stored in the specification data storage 11b. The values can be read from the double logarithmic graph representing the safe operating area 70 of the transistor 50 illustrated in FIG. 4. For example, the value of the drain current I_{d} and the value of the drain-source voltage V_{ds} at a point 75a illustrated in FIG. 4 and a value of the drain current I_{d} and a value of the drain-source voltage V_{ds} at a point 75b illustrated in FIG. 4 are stored in the specification data storage 11b.

The data determining circuitry 12 is a part that determines to what classification CL of a plurality of classifications CL sampling data Sd included in the inspection data group DG corresponds. The plurality of classifications CL are classifications corresponding to a plurality of safe operating areas 70 based on a pulse application time, that is, a pulse width tw, of a pulse current applied to the transistor 50. The plurality of classifications CL in this embodiment are determined on the basis of a magnitude of a gradient of a change over time of the drain current I_{d} in the inspection data group DG. Specifically, in the example illustrated in FIG. 3, the plurality of classifications CL include a first classification CL1, a second classification CL2, and a third classification CL3.

The first classification CL1 is a classification in which the gradient of the change over time of the drain current I_{d} is equal to or greater than a value α and equal to or less than a value β. The value α is a negative value, and the value β is a positive value. The absolute value of the value α and the absolute value of the value β may be the same or different from each other. The second classification CL2 is a classification in which the gradient of the change over time of the drain current I_{d} is greater than the value β. The third classification CL3 is a classification in which the gradient of the change over time of the drain current I_{d} is less than the value. In the example illustrated in FIG. 3, the first section P1, the third section P3, and the fifth section P5 are included in the first classification CL1. The second section P2 is included in the second classification CL2. The fourth section P4 is included in the third classification CL3. That is, the second classification CL2 is a classification CL of sampling data Sd included in the turning-off section. The third classification CL3 is a classification CL of sampling data Sd included in the turning-off section. The first classification CL1 is a classification CL of sampling data Sd included in a section other than the turning-on section and the turning-off section. The absolute value of the gradient of the change over time of the drain current I_{d} in the first classification CL1 is less than the absolute value of the gradient of the change over time of the drain current I_{d} in the second classification CL2 and the third classification CL3. The value α is a determination value for the gradient at the time of turning-off (at the time of decreasing). The value β is a determination value for the gradient at the time of turning-on (at the time of increasing).

For example, when a time width of the second section P2 which is the turning-on section is large to a certain extent, the second section P2 may be considered as a section corresponding to a case in which a direct current flows in the transistor 50 and classified into the first classification CL1.

In a section in which the drain current I_{d} and the drain-source voltage V_{ds} change as in the second section P2 and the fourth section P4, the time width of each section can be considered to be a pulse width tw of a pulse current applied to the transistor 50. Here, in the section in which the drain current I_{d} and the drain-source voltage V_{ds} change, the time width of the section decreases as the absolute value of the gradient of the drain current I_{d} increases, and the time width of the section increases as the absolute value of the gradient of the drain current I_{d} decreases. Accordingly, by calculating the magnitude of the gradient of the drain current I_{d}, it is possible to determine with what pulse width tw the drain current I_{d} applied to the transistor 50 in each section of a predetermined time range TR corresponds to a pulse current.

The data determining circuitry 12 calculates a gradient of a change over time of a drain current I_{d} in the inspection data group DG. The data determining circuitry 12 according to this embodiment calculates the gradient for each piece of sampling data Sd included in the inspection data group DG. Specifically, the data determining circuitry 12 calculates a differential value I_{d}/dt obtained by differentiating the drain current I_{d} of the sampling data Sd as the gradient in the sampling data Sd, for example, using the sampling data Sd or the like before and after the sampling data Sd used to calculate the gradient. The data determining circuitry 12 determines to what classification CL of the plurality of classifications CL the sampling data Sd included in the inspection data group DG corresponds on the basis of the calculated vale of the gradient. In the following description, the gradient of the change over time of the drain current I_{d} in the inspection data group DG may be referred to as a gradient dI_{d}/dt.

The standard calculating circuitry 13 is a part that calculates the electrical standard of the transistor 50 on the basis of information on the specifications of the transistor 50. The standard calculating circuitry 13 according to this embodiment calculates the safe operating area 70 of the transistor 50 as the electrical standard of the transistor 50. Specifically, the standard calculating circuitry 13 derives functions indicating the current limit area 71, the voltage limit area 72, the on-resistance limit area 73, the thermal limit area 74, and the secondary breakdown area 75 on the basis of numerical values associated with the specifications of the transistor 50 and calculates the safe operating area 70 as the electrical standard. The standard calculating circuitry 13 according to this embodiment calculates the electrical standard, that is, the safe operating area 70, on the basis of the rated value of current of the transistor 50, that is, the rated value of the drain current I_{d}, the rated value of voltage of the transistor 50, that is, the rated value of the drain-source voltage V_{ds}, the maximum value of the on-resistance of the transistor 50, the permissible loss P_{d} of the transistor 50, and the value of the drain current I_{d} and the value of the drain-source voltage V_{ds} associated with the secondary breakdown of the transistor 50. In the following description, the safe operating area 70 calculated by the standard calculating circuitry 13 is referred to as a safe operating area 70S.

The standard calculating circuitry 13 according to this embodiment can calculate the electrical standard, that is, the safe operating area 70S, corresponding to the plurality of classifications CL. The standard calculating circuitry 13 according to this embodiment calculates a safe operating area 70A corresponding to the first classification CL1, a safe operating area 70B corresponding to the second classification CL2, and a safe operating area 70C corresponding to the third classification CL3. The safe operating area 70A in the first classification CL1 corresponds to a safe operating area when a direct current flows in the transistor 50. The safe operating areas 70B and 70C in the second classification CL2 and the third classification CL3 correspond to safe operating areas when a pulse current flows in the transistor 50. The safe operating area 70B in the second classification CL2 corresponds to a safe operating area when the pulse width tw of the pulse current flowing in the transistor 50 is greater than that in the safe operating area 70C in the third classification CL3. Since the plurality of safe operating areas 70S calculated by the standard calculating circuitry 13 are classified on the basis of a time (the pulse width tw) in which a current flows in the transistor 50, the plurality of electrical standards calculated by the standard calculating circuitry 13 can be said to include temporal standards of the transistor 50.

The current limit area 71 is expressed by I_{d}=Iᵣ, where I_{d} is a drain current and Iᵣ is the rated value of the drain current I_{d}. The standard calculating circuitry 13 can derive a function representing the current limit area 71 by substituting the rated value of the drain current I_{d} stored in the specification data storage 11b into Iᵣ in the Expression.

The voltage limit area 72 is expressed by V_{ds}=Vᵣ, where V_{ds} is a drain-source voltage and Vᵣ is the rated value of the drain-source voltage V_{ds}. The standard calculating circuitry 13 can derive a function representing the voltage limit area 72 by substituting the rated value of the drain-source voltage V_{ds} stored in the specification data storage 11b into Vᵣ in the Expression.

The on-resistance limit area 73 is expressed by I_{d}=V_{ds}/(R_{ds}) where I_{d} is a drain current, V_{ds} is a drain-source voltage, and R_{ds} is a maximum value of an on-resistance. The standard calculating circuitry 13 can derive a function representing the on-resistance limit area 73 by substituting the maximum value of the on-resistance stored in the specification data storage 11b into R_{ds} in the Expression.

The thermal limit area 74 is expressed by I_{d}=P_{d}/V_{ds} where I_{d} is a drain current, Vas is a drain-source voltage, and P_{d} is a permissible loss. The permissible loss P_{d} is expressed by P_{d}=(T_{ch}−T_{c})/rₜₕ, where T_{ch} is a channel temperature, T is a case temperature, and rₜₕ is a transient thermal resistance. The standard calculating circuitry 13 can derive a function representing the thermal limit area 74 by substituting the values of the channel temperature T_{ch}, the case temperature T_{c}, and the transient thermal resistance rₜₕ stored in the specification data storage 11b into the Expressions. When the permissible loss P_{d} is described in the specification table of the transistor 50, the numerical value of the permissible loss P_{d} described in the specification table may be stored in the specification data storage 11b, and the stored value may be used as the value of the permissible loss P_{d}.

The secondary breakdown area 75 is expressed by Expression (1), where I_{d} is a drain current and V_{ds} is a drain-source voltage.

$${I}_{d} = {C}_{1} {V}_{ds}^{{C}_{2}} \qquad ( 1 )$$

$${C}_{1} = \frac{{log}_{10} {I}_{d 1} - {log}_{10} {I}_{d 2}}{{log}_{10} {V}_{d s 1} - {log}_{10} {V}_{ds 2}}$$

$${C}_{2} = \frac{{I}_{d 1}}{{V}_{ds 1} \times {C}_{1}}$$

Here, I_{d1} is a value of the drain current I_{d} at an arbitrary point on the area line indicating the secondary breakdown area 75 in the double logarithmic graph of the safe operating area 70 described in the data sheet of the transistor 50, and V_{ds1} is a value of the drain-source voltage V_{ds} at the arbitrary point. I_{d2} is a value of the drain current I_{d} at another arbitrary point on the area line indicating the secondary breakdown area 75 in the double logarithmic graph of the safe operating area 70 described in the data sheet of the transistor 50, and V_{ds2} is a value of the drain-source voltage V_{ds} at the other arbitrary point.

The standard calculating circuitry 13 can derive a function representing the secondary breakdown area 75 by substituting the values of the drain current I_{d} and the values of the drain-source voltage V_{ds} at two arbitrary points on the area line indicating the secondary breakdown area 75 which are stored in the specification data storage 11b into Expression (1). In this embodiment, the value of the drain current I_{d} at the point 75a illustrated in FIG. 4 is substituted into I_{d1}, and the value of the drain-source voltage V_{ds} of the point 75a is substituted into V_{ds1}. The value of the drain current La at the point 75b illustrated in FIG. 4 is substituted into I_{d2}, and the value of the drain-source voltage Vas of the point 75b is substituted into V_{ds2}.

The standard calculating circuitry 13 prepares a data table according to the sampling data Sd included in the inspection data group DG on the basis of the functions defining the safe operating area 70S. The standard calculating circuitry 13 generates a data group of values of the drain current I_{d} in the current limit area 71 corresponding to the values of the drain-source voltage V_{ds} in the sampling data Sd, that is, the rated values of the drain current I_{d} stored in the specification data storage 11b and prepares the data table of the current limit area 71. The standard calculating circuitry 13 generates a data group of values of the drain-source voltage V_{ds} in the voltage limit area 72 corresponding to the values of the drain current I_{d} in the sampling data Sd, that is, the rated values of the drain-source voltage V_{ds} stored in the specification data storage 11b and prepares the data table of the voltage limit area 72.

The standard calculating circuitry 13 prepares data tables of the on-resistance limit area 73, the thermal limit area 74, and the secondary breakdown area 75 corresponding to the sampling data Sd by substituting the values of the drain-source voltage V_{ds} of the sampling data Sd included in the inspection data group DG into functions having I_{d} and V_{ds} as variables, that is, the function representing the on-resistance limit area 73, the function representing the thermal limit area 74, and the function representing the secondary breakdown area 75, out of the functions defining the safe operating area 70S.

The standard calculating circuitry 13 plots the values in the prepared data tables on a double logarithmic graph and prepares a double logarithmic graph of the safe operating area 70S corresponding to the safe operating area 70 described in the data sheet of the transistor 50. In the embodiment, the standard calculating circuitry 13 prepares the double logarithmic graph of the safe operating area 70S corresponding to each of the plurality of classifications CL.

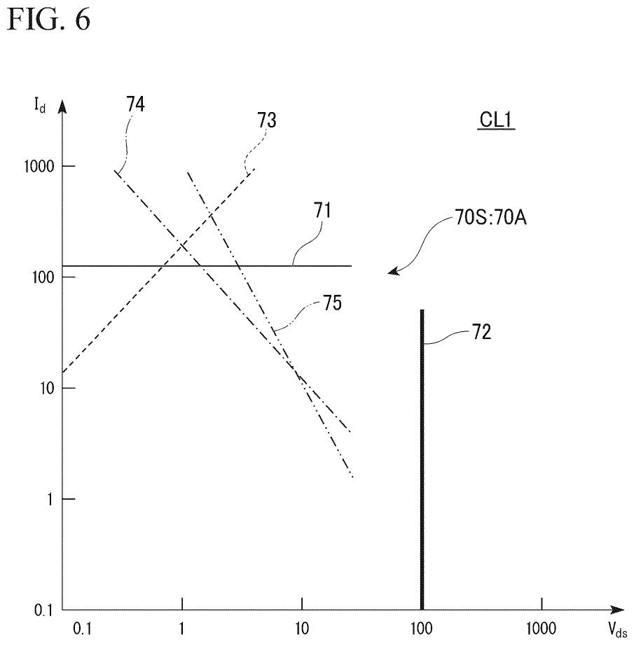

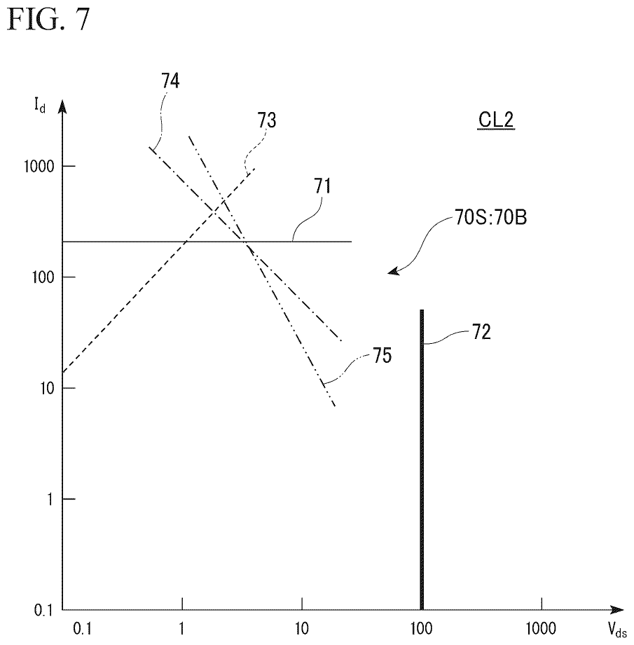

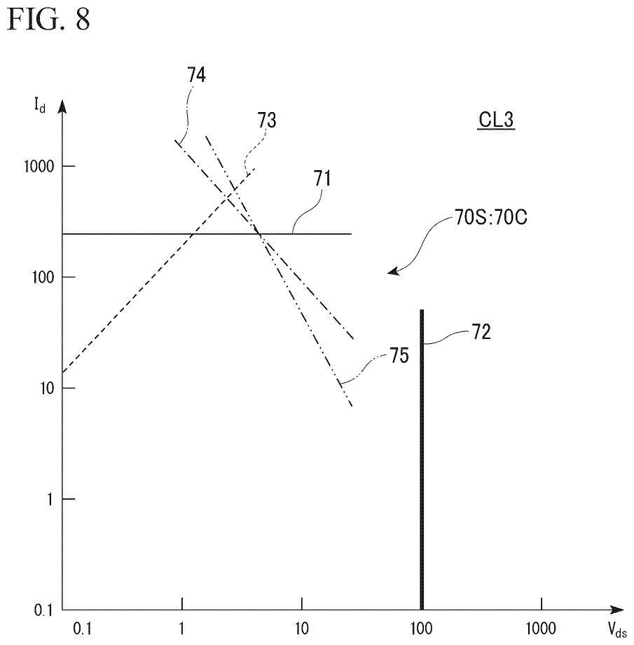

FIG. 6 is a diagram illustrating an example of a double logarithmic graph of the safe operating area 70A corresponding to the first classification CL1 prepared by the standard calculating circuitry 13. FIG. 7 is a diagram illustrating an example of a double logarithmic graph of the safe operating area 70B corresponding to the second classification CL2 prepared by the standard calculating circuitry 13. FIG. 8 is a diagram illustrating an example of a double logarithmic graph of the safe operating area 70C corresponding to the third classification CL3 prepared by the standard calculating circuitry 13. In FIGS. 6 to 8, the horizontal axis represents the drain-source voltage V_{ds}, and the vertical axis represents the drain current Ia. In FIGS. 6 to 8, the area lines of the current limit area 71, the voltage limit area 72, the on-resistance limit area 73, the thermal limit area 74, and the secondary breakdown area 75 are schematically indicated by straight lines, but the area lines indicating the areas are actually formed by the plotted values in the data table. As illustrated in FIGS. 6 to 8, the voltage limit area 72 and the on-resistance limit area 73 are the same in the safe operating area 70S of any classification CL.

The standard calculating circuitry 13 adjusts the electrical standard on the basis of a temperature of the transistor 50. The temperature of the transistor 50 is a temperature associated with the transistor 50 and may be a temperature at any position on the transistor 50 or may be an ambient temperature of the transistor 50. In this embodiment, the standard calculating circuitry 13 adjusts the thermal limit area 74 and the secondary breakdown area 75 out of the areas defining the safe operating area 70S on the basis of the case temperature T_{c} as the temperature of the transistor 50. Specifically, the standard calculating circuitry 13 adjusts the thermal limit area 74 and the secondary breakdown area 75 by adjusting the value of the permissible loss P_{d}.

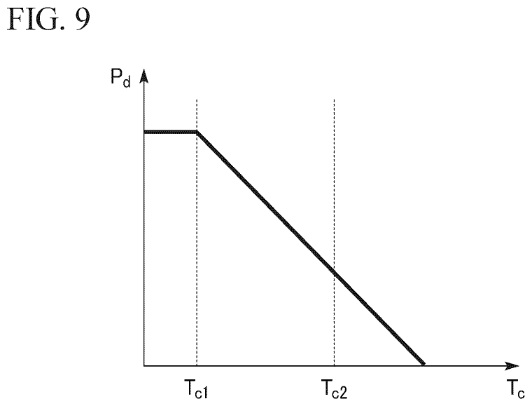

FIG. 9 is a diagram illustrating an example of a graph representing a change of the permissible loss P_{d} with respect to the case temperature T_{c} of the transistor 50. In FIG. 9, the horizontal axis represents the case temperature T_{c}, and the vertical axis represents the permissible loss P_{d}. In the example illustrated in FIG. 9, in an area in which the case temperature T_{c} is equal to or greater than the standard case temperature T_{c1}, the permissible loss P_{d} decreases linearly as the case temperature T_{c} increases. From this relationship, the permissible loss P_{d2} at which the case temperature T_{c} is calculated as a case temperature T_{c2} higher than the case temperature T_{c1} is expressed by the P_{d2}=P_{d1}×(T_{ch}−T_{c2})/(T_{ch}−T_{c1}), where P_{d1} is a permissible loss calculated using the standard case temperature T_{c1} as the case temperature T_{c} and T_{ch} is a channel temperature. The case temperature T_{c2} is, for example, a maximum value of the case temperature T_{c} assumed to be reached with an increase in temperature of the transistor 50. For example, the case temperature T_{c2} is 120° C.

The standard calculating circuitry 13 can adjust the thermal limit area 74 when the case temperature T_{c} is set to the case temperature T_{c1} to the thermal limit area 74 when the case temperature T_{c} is set to the case temperature T_{c2} by changing the permissible loss P_{d} in the function indicating the thermal limit area 74 from the permissible loss P_{d1} to the permissible loss P_{d2}.

The standard calculating circuitry 13 can adjust the secondary breakdown area 75 when the case temperature T_{c} is set to the case temperature T_{c1} to the secondary breakdown area 75 when the case temperature T_{c} is set to the case temperature T_{c2} by multiplying the right term of Expression (1) indicating the secondary breakdown area 75 by a ratio of the permissible loss P_{d2} to the permissible loss P_{d1}. Specifically, the standard calculating circuitry 13 can acquire the function of the adjusted secondary breakdown area 75 using Expression (2).

$${I}_{d} = {C}_{1} {V}_{ds}^{{C}_{2}} \times \frac{{P}_{d 2}}{{P}_{d 1}} \qquad ( 2 )$$

Here, C₁ and C₂ are the same as in Expression (1).

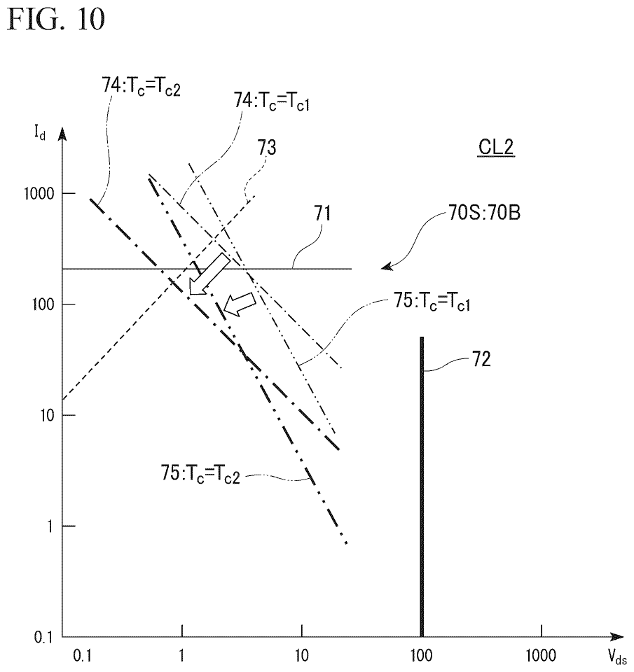

FIG. 10 is a diagram illustrating an example in which the double logarithmic graph of the safe operating area 70B corresponding to the second classification CL2 is adjusted. In FIG. 10, the horizontal axis represents the drain-source voltage V_{ds}, and the vertical axis represents the drain current I_{d}. When the case temperature T_{c} changes from the case temperature T_{c1} to the case temperature T_{c2} higher than the case temperature T_{c1} as illustrated in FIG. 10, the value of the drain current I_{d} of the thermal limit area 74 and the secondary breakdown area 75 decreases, and the safe operating area 70B is narrowed. In this way, the standard calculating circuitry 13 can perform temperature derating on the safe operating area 70S.

The standard determining circuitry 14 determines whether the inspection data group DG satisfies the electrical standard calculated by the standard calculating circuitry 13. In this embodiment, the standard determining circuitry 14 determines whether the sampling data Sd int he inspection data group DG is included in the safe operating area 70S calculated by the standard calculating circuitry 13. More specifically, the standard determining circuitry 14 plots the sampling data Sd classified into a plurality of classifications CL on the double logarithmic graph of the safe operating area 70S prepared by the standard calculating circuitry 13 for each of the plurality of classifications CL and determines whether the sampling data Sd is included in the safe operating area 70S of the plotted double logarithmic graph. That is, in this embodiment, the standard determining circuitry 14 performs determination of the sampling data Sd using the safe operating area 70S corresponding to each classification CL depending on the classification CL in which the sampling data Sd to be determined is included. In other words, the standard determining circuitry 14 changes the electrical standard that is automatically used for the inspection data group DG according to the classification CL determined by the data determining circuitry 12.

When the sampling data Sd is included in all of the current limit area 71, the voltage limit area 72, the on-resistance limit area 73, the thermal limit area 74, and the secondary breakdown area 75 defining the safe operating area 70S, the standard determining circuitry 14 determines that the sampling data Sd is included in the safe operating area 70S and the sampling data Sd satisfies the electrical standard of the transistor 50. When the sampling data Sd is not included in one or more areas of the current limit area 71, the voltage limit area 72, the on-resistance limit area 73, the thermal limit area 74, and the secondary breakdown area 75, the standard determining circuitry 14 determines that the sampling data Sd is not included in the safe operating area 70S and the sampling data Sd does not satisfy the electrical standard of the transistor 50. The standard determining circuitry 14 outputs the sampling data Sd determined not to satisfy the electrical standard in the inspection data group DG to the waveform generating circuitry 15.

When the sampling data Sd is included in the current limit area 71, it means that the value of the drain current I_{d} of the sampling data Sd is less than the value of the drain current I_{d} of the area line of the current limit area 71, that is, the rated value of the drain current I_{d}. When the sampling data Sd is included in the voltage limit area 72, it means that the value of the drain-source voltage V_{ds} of the sampling data Sd is less than the value of the drain-source voltage V_{ds} of the area line of the voltage limit area 72, that is, the rated value of the drain-source voltage V_{ds}. When the sampling data Sd is included in the on-resistance limit area 73, the thermal limit area 74, and the secondary breakdown area 75, it means that the value of the drain current I_{d} of the sampling data Sd at the drain-source voltage V_{ds} of the sampling data Sd is less than the values of the drain current I_{d} on the area lines of the on-resistance limit area 73, the thermal limit area 74, and the secondary breakdown area 75.

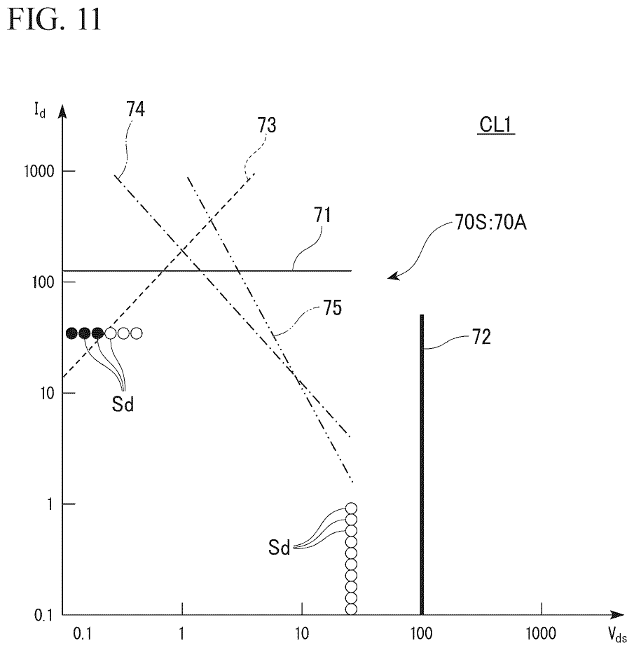

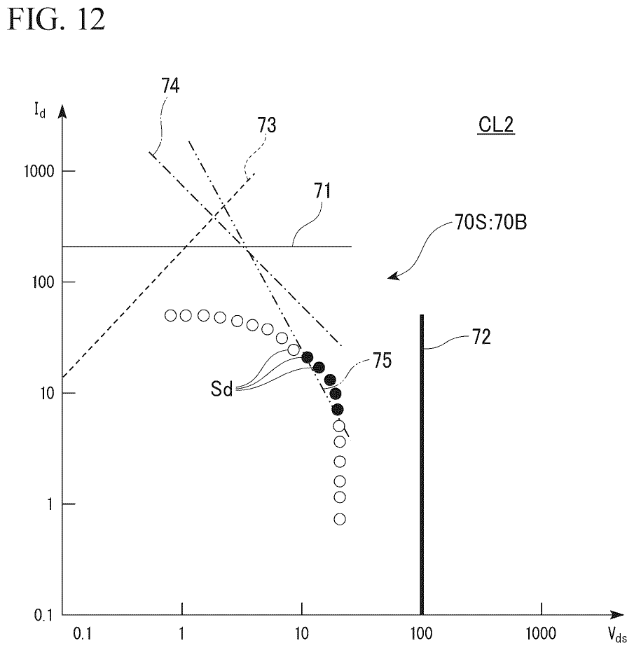

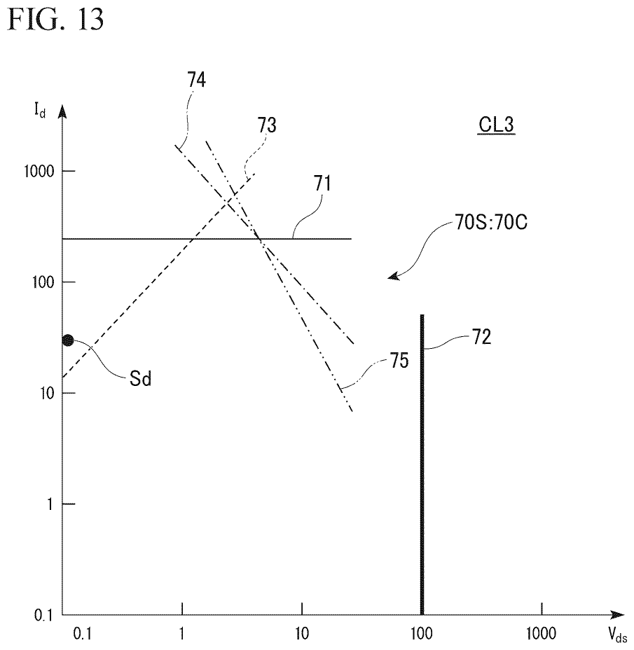

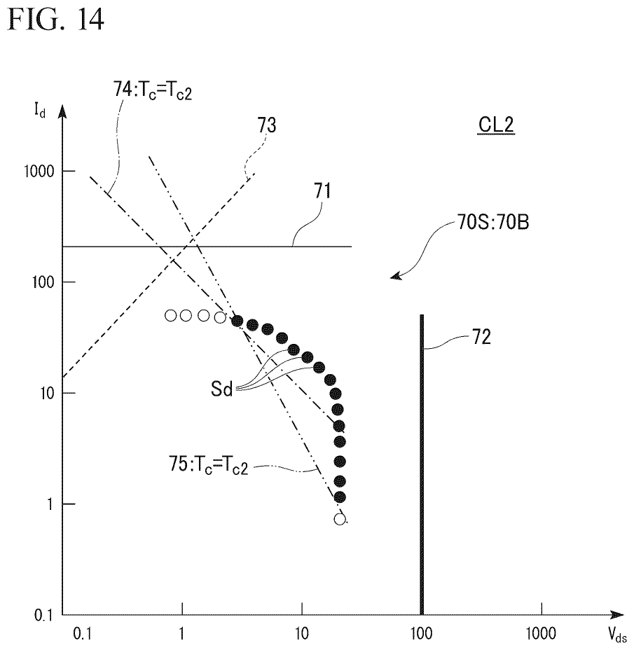

FIG. 11 is a diagram illustrating an example in which sampling data Sd determined to be in the first classification CL1 is plotted on the double logarithmic graph of the safe operating area 70A of the first classification CL1. FIG. 12 is a diagram illustrating an example in which sampling data Sd determined to be in the second classification CL2 is plotted on the double logarithmic graph of the safe operating area 70B of the second classification CL2. FIG. 13 is a diagram illustrating an example in which sampling data Sd determined to be in the third classification CL3 is plotted on the double logarithmic graph of the safe operating area 70C of the third classification CL3. FIG. 14 is a diagram illustrating an example in which sampling data Sd determined to be in the second classification CL2 is plotted on the adjusted double logarithmic graph of the safe operating area 70B of the second classification CL2.

In FIGS. 11 to 14, the horizontal axis represents the drain-source voltage V_{ds}, and the vertical axis represents the drain current I_{d}. In FIGS. 11 to 14, the area lines of the current limit area 71, the voltage limit area 72, the on-resistance limit area 73, the thermal limit area 74, and the secondary breakdown area 75 are schematically indicated by straight lines, but the area lines indicating the areas are actually formed by the plotted values in the data table.

In FIGS. 11 to 14, the safe operating areas 70S, that is, the sampling data Sd satisfying the electrical standards, are indicated by white circles, and the sampling data Sd not satisfying the electrical standards is indicated by black circles. The standard determining circuitry 14 outputs the sampling data Sd determined not to satisfy the electrical standard to the waveform generating circuitry 15. The standard determining circuitry 14 may output the double logarithmic graphs on which the sampling data Sd has been plotted to the display 30 such that the graphs are displayed on the display 30. The standard determining circuitry 14 may all of the sampling data Sd in the double logarithmic graphs displayed on the display 30 in a plot of the same color.

The waveform generating circuitry 15 generates time waveforms W of the drain current I_{d} and the drain-source voltage V_{ds} in the inspection data group DG. Specifically, the waveform generating circuitry 15 plots the sampling data Sd included in the inspection data group DG stored in the inspection data storage 11a on the time axis and generates the time waveforms W of the drain current I_{d} and the drain-source voltage V_{ds}. The waveform generating circuitry 15 displays the sampling data Sd not satisfying the electrical standards output from the standard determining circuitry 14 in the inspection data group DG on the prepared time waveforms W.

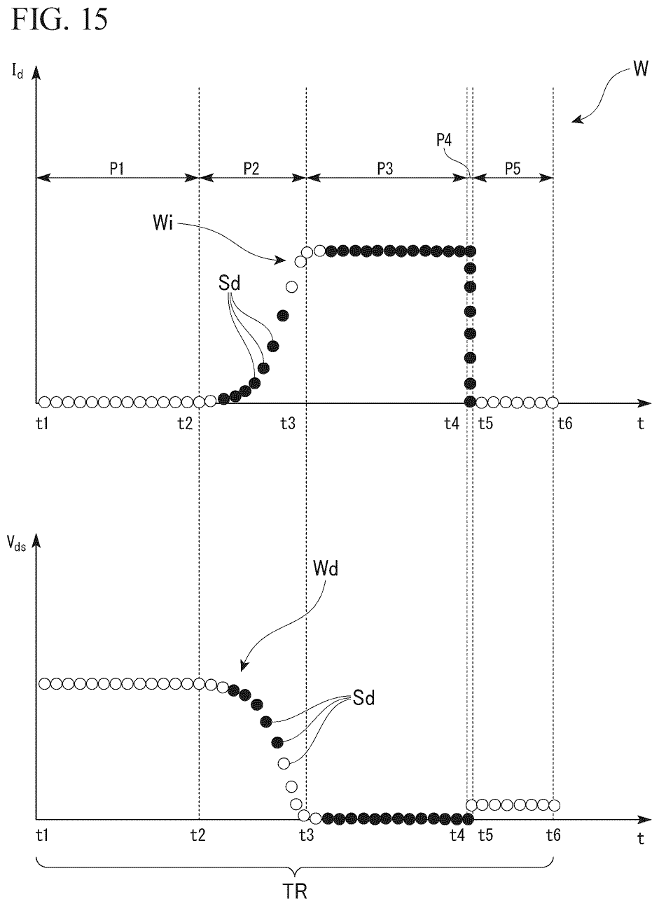

FIG. 15 is a diagram illustrating an example of the time waveform W generated by the waveform generating circuitry 15. The upper graph of FIG. 15 is a graph representing a time waveform Wi of the drain current I_{d}. The lower graph of FIG. 15 is a graph representing a time waveform Wd of the drain-source voltage V_{ds}. In the upper graph of FIG. 15, the horizontal axis represents the time t, and the vertical axis represents the drain current Ia. In the lower graph of FIG. 15, the horizontal axis represents the time t, and the vertical axis represents the drain-source voltage V_{ds}. As illustrated in FIG. 15, the waveform generating circuitry 15 emphasizes and displays the sampling data Sd not satisfying the electrical standard on the time waveforms Wi and Wd. In the example illustrated in FIG. 15, the sampling data Sd satisfying the electrical standards is indicated by white circles, and the sampling data Sd not satisfying the electrical standards is indicated by black circles. The waveform generating circuitry 15 outputs the prepared time waveforms W to the display 30 such that the prepared time waveforms are displayed on the display 30. Accordingly, an operator can ascertain what of the inspection data group DG does not satisfy the safe operating area 70S of the transistor 50, that is, the electrical standards.

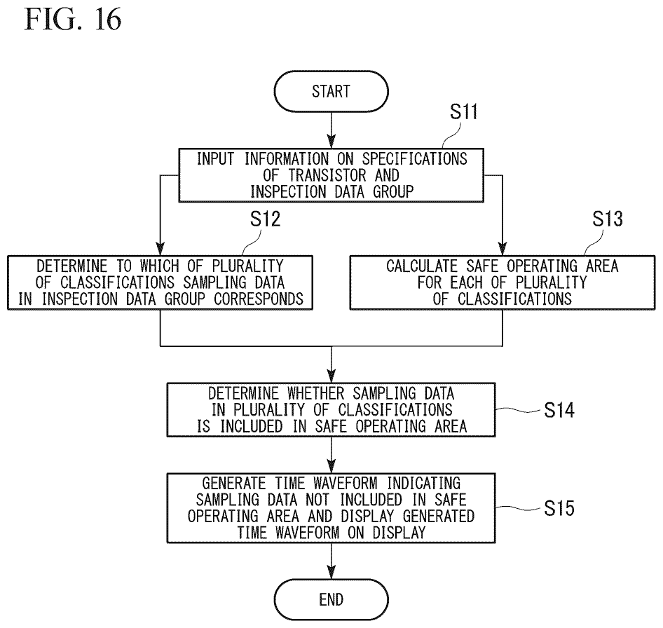

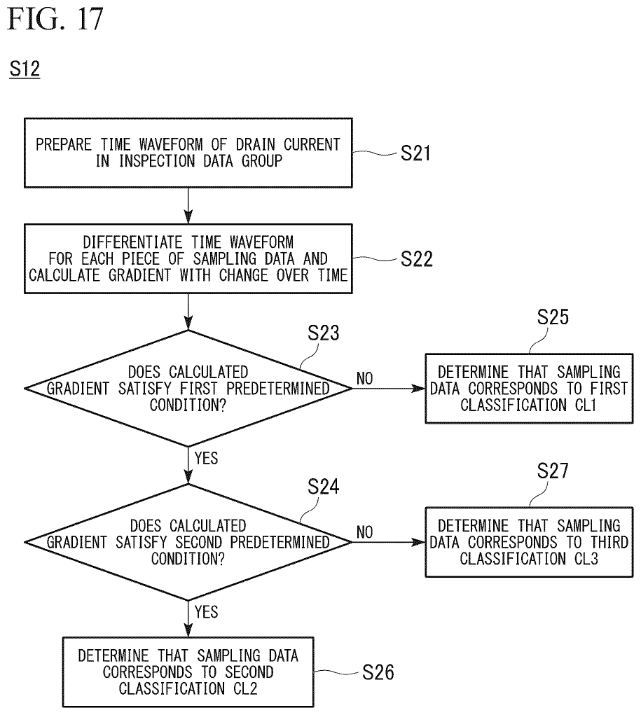

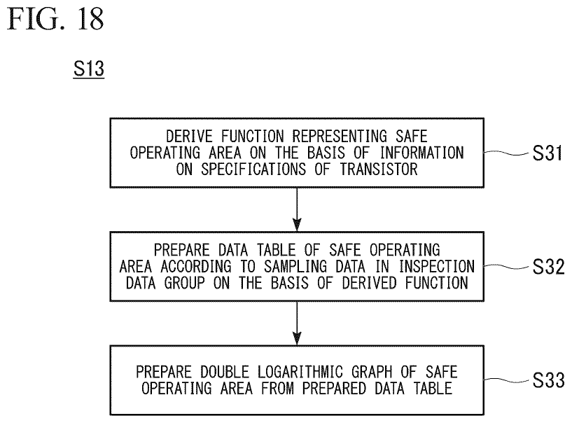

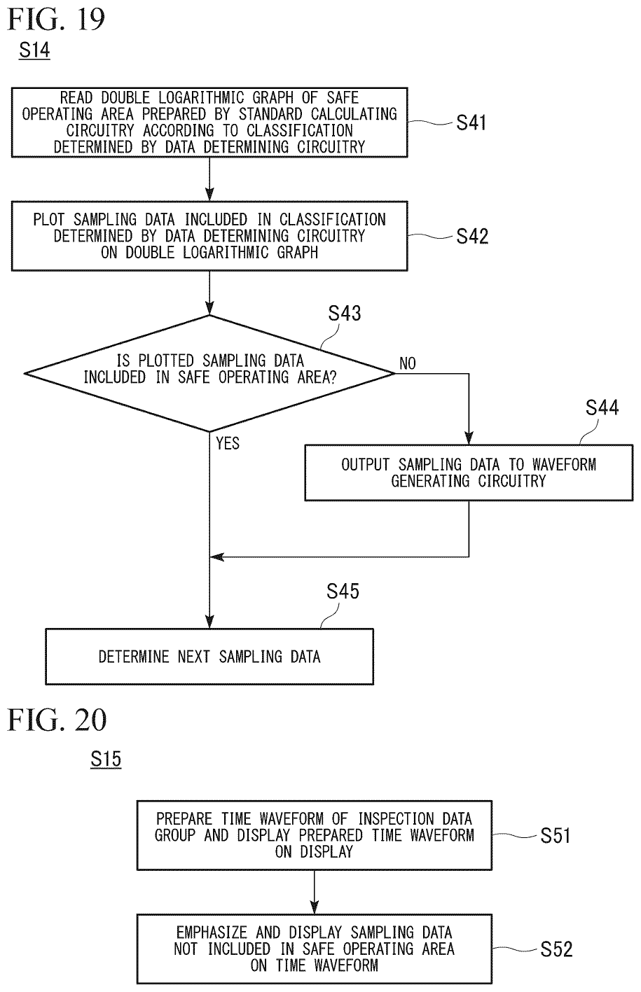

An inspection method using the inspection device 100 will be described below. FIG. 16 is a flowchart illustrating a calculation flow that is performed by the calculation circuitry 10. FIG. 17 is a flowchart illustrating an example of a process flow that is performed by the data determining circuitry 12. FIG. 18 is a flowchart illustrating an example of a process flow that is performed by the standard calculating circuitry 13. FIG. 19 is a flowchart illustrating an example of a process flow that is performed by the standard determining circuitry 14. FIG. 20 is a flowchart illustrating an example of a process flow that is performed by the waveform generating circuitry 15.

As illustrated in FIG. 16, the calculation circuitry 10 receives information on the specifications of the transistor 50 and the inspection data group DG via the operator 20 (Step S11), determines to which of a plurality of classifications CL sampling data Sd in the inspection data group DG corresponds (Step S12), and calculates a safe operating area 70S, that is, an electrical standard, for each of the plurality of classifications CL (Step S13).

The calculation circuitry 10 may sequentially perform Step S12 and Step S13. In this case, any of Step S12 and Step S13 may be performed earlier. When determination of a transistor 50 having the same specifications has been performed before this inspection and information on the specifications of the transistor 50 input previously are stored in the storage 11, inputting information on the specification of the transistor 50 in Step S11 may be skipped.

Step S12 is performed by the data determining circuitry 12. As illustrated iN FIG. 17, the data determining circuitry 12 prepares a time waveform of the drain current I_{d} in the inspection data group DG (Step S21). The time waveform is, for example, the same waveform as the time waveform illustrated in the upper graph of FIG. 3. The data determining circuitry 12 differentiates the time waveform of the drain current I_{d} for each piece of sampling data Sd to calculate a gradient dI_{d}/dt of the change over time (Step S22). In this way, the inspection method according to this embodiment includes calculating the gradient dI_{d}/dt of the change over time of the value of current in the inspection data group DG.

The data determining circuitry 12 determines whether the calculated gradient dI_{d}/dt satisfies a first predetermined condition (Step S23). The first predetermined condition is that the gradient dI_{d}/dt of the sampling data Sd is less than the value α or greater than the value β. When the calculated gradient dI_{d}/dt does not satisfy the first predetermined condition (Step S23: NO), the data determining circuitry 12 determines that the sampling data Sd corresponds to the first classification CL1 (Step S25).

On the other hand, when the calculated gradient dI_{d}/dt satisfies the first predetermined condition (Step S23: YES), the data determining circuitry 12 determines whether the calculated gradient dI_{d}/dt satisfies a second predetermined condition (Step S24). The second predetermined condition is that the gradient dI_{d}/dt of the sampling data Sd is greater than the value β. When the calculated gradient dI_{d}/dt satisfies the second predetermined condition (Step S24: YES), the data determining circuitry 12 determines that the sampling data Sd corresponds to the second classification CL2 (Step S26). On the other hand, when the calculated gradient dI_{d}/dt does not satisfy the second predetermined condition (Step S24: NO), the data determining circuitry 12 determines that the sampling data Sd corresponds to the third classification CL3 (Step S27). The data determining circuitry 12 performs the determination on all the sampling data Sd included in the inspection data group DG and determines to which classification CL the sampling data Sd corresponds. In this way, the inspection method according to this embodiment includes determining to which classification CL of a plurality of classifications CL classified on the basis of the magnitude of the gradient dI_{d}/dt the sampling data Sd included in the inspection data group DG corresponds.

Step S13 is performed by the standard calculating circuitry 13. As illustrated in FIG. 18, the standard calculating circuitry 13 derives a function indicating a safe operating area 70S, that is, an electrical standard, on the basis of information on the specifications of the transistor 50 (Step S31). In this embodiment, the standard calculating circuitry 13 derives the function indicating the safe operating area 70S for each of the plurality of classifications CL. Specifically, the standard calculating circuitry 13 derives the functions representing the current limit area 71, the voltage limit area 72, the on-resistance limit area 73, the thermal limit area 74, and the secondary breakdown area 75 as described above. That is, the inspection method according to this embodiment includes calculating the electrical standards on the basis of the rated value of current of the transistor 50, the rated value of voltage of the transistor 50, the maximum value of the on-resistance of the transistor 50, the permissible loss P_{d} of the transistor 50, and the value of current and the value of voltage associated with a secondary breakdown of the transistor 50.

The standard calculating circuitry 13 prepares a data table of the safe operating area 70S according to the sampling data Sd in the inspection data group DG on the basis of the derived functions (Step S32). In this embodiment, the standard calculating circuitry 13 prepares the data table of the safe operating area 70S for each of the plurality of classifications CL. The standard calculating circuitry 13 prepares a double logarithmic graph of the safe operating area 70S in the prepared data table (Step S33). In this embodiment, the standard calculating circuitry 13 prepares the double logarithmic graph of the safe operating area 70S for each of the plurality of classifications CL. The double logarithmic graph of the safe operating area 70S prepared by the standard calculating circuitry 13 in Step S33 is, for example, the graphs illustrated in FIGS. 6 to 8.

For example, when an operator inputs an instruction to perform temperature derating to the inspection device 100, the standard calculating circuitry 13 adjusts the electrical standards on the basis of the case temperature T_{c} of the transistor 50 in Step S13 as described above with reference to FIG. 10.

As described above, the inspection method according to this embodiment includes calculating the electrical standard of the transistor 50 on the basis of the information on the specifications of the transistor 50, calculating the electrical standard corresponding to each of the plurality of classifications CL, and adjusting the electrical standard on the basis of the temperature of the transistor 50.

As illustrated in FIG. 16, after having performed Steps S12 and S13, the calculation circuitry 10 determines whether the sampling data Sd is included in the safe operating area 70S for each of the plurality of classifications CL (Step S14). Step S14 is performed by the standard determining circuitry 14. As illustrated in FIG. 19, in Step S14, the standard determining circuitry 14 reads the double logarithmic graph of the safe operating area 70S prepared by the standard calculating circuitry 13 according to the classification CL determined by the data determining circuitry 12 (Step S41). The standard determining circuitry 14 plots the sampling data Sd included in the classification CL determined by the data determining circuitry 12 on the double logarithmic graph as described above with reference to FIGS. 11 to 14 (Step S42). The standard determining circuitry 14 determines whether the plotted sampling data Sd is included in the safe operating area 70S (Step S43). When the sampling data Sd is included in the safe operating area 70S, the standard determining circuitry 14 performs the determination of next sampling data Sd in the same way (Step S45). On the other hand, when the sampling data Sd is not included in the safe operating area 70S, the standard determining circuitry 14 outputs the sampling data Sd to the waveform generating circuitry 15 (Step S44) and performs the determination of next sampling data Sd in the same way (Step S45).

The standard determining circuitry 14 performs Step S14 until all the pieces of sampling data Sd included in the inspection data group DG have been completely determined. So long as all the pieces of sampling data Sd are determined, the standard determining circuitry 14 may perform the determination of the sampling data Sd in any order. The standard determining circuitry 14 may perform the determination of the sampling data Sd for each of the plurality of classifications CL or may perform the determination of the sampling data Sd included in the inspection data group DG piece by piece in a time series.

As described above, the inspection method according to this embodiment includes determining whether the inspection data group DG including the temporal sampling data Sd of the value of current flowing in the transistor 50 in a predetermined time range TR and the value of voltage applied to the transistor 50 satisfies the electrical standards, outputting the sampling data Sd determined not to satisfy the electrical standard in the inspection data group DG, and changing the electrical standard automatically used to determine the inspection data group DG according to the determined classification CL.

As illustrated in FIG. 16, after having performed Step S14, the calculation circuitry 10 generates a time waveform W on which the sampling data Sd not included in the safe operating area 70S is displayed and displays the generated time waveform W on the display 30 (Step S15). Step S15 is performed by the waveform generating circuitry 15. As illustrated in FIG. 20, in Step S15, the waveform generating circuitry 15 generates the time waveform W of the inspection data group DG and displays the generated time waveform W on the display 30 as described above with reference to FIG. 15 (Step S51). The waveform generating circuitry 15 emphasizes and displays the sampling data Sd not included in the safe operating area 70S on the time waveform W (Step S52). In Step S52, the waveform generating circuitry 15 emphasizes and displays the sampling data Sd not included in the safe operating area 70S on the time waveform W, for example, by plotting the sampling data Sd not included in the safe operating area 70S on the time waveform W in a color different from that for the sampling data Sd included in the safe operating area 70S. In this way, the inspection method according to this embodiment includes generating the time waveform W of the value of current and the value of voltage in the inspection data group DG and displaying the sampling data Sd not satisfying the electrical standard in the inspection data group DG on the time waveform W.

The operation inspection using the inspection device 100 ends in this way. An operator can easily ascertain what of the inspection data group DG plotted on the time axis is not included in the safe operating area 70S, that is, does not satisfy the electrical standard, by watching the time waveform W displayed on the display 30.

At least some functions of the calculation circuitry 10 are realized, for example, by causing a processor such as a CPU to execute a program, that is, software, stored in the storage 11. At least some functions of the constituents of the calculation circuitry 10 may be realized, for example, by hardware including a circuitry such as a large scale integration (LSI) circuit, an application-specific integrated circuit (ASIC), a field-programmable gate array (FPGA), or a graphics processing unit (GPU) or may be cooperatively realized by software and hardware.

According to this embodiment, the inspection device 100 is an inspection device for performing operation inspection of a circuit 40 including a transistor 50 and includes: a standard calculating circuitry 13 configured to calculate an electrical standard (a safe operating area 70S) of the transistor 50 on the basis of information on specifications of the transistor 50; and a standard determining circuitry 14 configured to determine whether an inspection data group DG including temporal sampling data Sd of a value of current (a value of a drain current I_{d}) flowing in the transistor 50 in a predetermined time range TR and a value of voltage (a value of a drain-source voltage V_{ds}) applied to the transistor 50 satisfies the electrical standard and to output sampling data Sd which is determined not to satisfy the electrical standard in the inspection data group DG. Accordingly, by only allowing an operator to input the information on the specifications of the transistor 50 to the inspection device 100, the electrical standard of the transistor 50 is automatically calculated, and sampling data Sd not satisfying the electrical standard in the inspection data group DG is output. As a result, an operator can easily inspect whether the sampling data Sd in the inspection data group DG satisfies the electrical standard of the transistor 50 by only inputting some numerical values which are minimally required for easily reading them from a specification table or the like to the inspection device 100 without directly inputting the electrical standard of the transistor 50 to the inspection device 100. Accordingly, unlike a case in which the electrical standard of the transistor 50 is directly input by the operator, it is possible to secure accuracy of the electrical standard used to determine the inspection data group DG. As a result, it is possible to decrease a workload required for the operation inspection while securing the accuracy of the operation inspection of the circuit 40 including the transistor 50.

The inspection data group DG includes temporal sampling data Sd of the value of current flowing in the transistor 50 in the predetermined time range TR and the value of voltage applied to the transistor 50. Accordingly, since what sampling data Sd in the inspection data group DG does not satisfy the electrical standard of the transistor 50 can be ascertained, the operator can easily ascertain at what position on the time axis the value of current flowing in the transistor 50 and the value of voltage applied to the transistor 50 do not satisfy the electrical standard when the circuit 40 operates in the predetermined time range TR. As a result, the operator can easily investigate causes the operation of the circuit 40 does not satisfy the electrical standard of the transistor 50 and easily take measures for causing the operation of the circuit 40 to satisfy the electrical standard of the transistor 50. Accordingly, it is possible to facilitate design of the circuit 40 including the transistor 50.

According to the embodiment, the inspection device 100 further includes a data determining circuitry 12 configured to calculate a gradient dI_{d}/dt of a change over time of the value of the drain current I_{d} in the inspection data group DG and to determine to which of a plurality of classifications CL which are classified on the basis of a magnitude of the gradient dI_{d}/dt the sampling data Sd included in the inspection data group DG corresponds. The standard calculating circuitry 13 can calculate the electrical standard corresponding to each of the plurality of classifications CL. The standard determining circuitry 14 changes the electrical standard automatically used to determine the inspection data group DG according to the classification CL determined by the data determining circuitry 12. As described above, when the drain current I_{d} changes, a length of a period in which the drain current I_{d} changes becomes shorter as the absolute value of the gradient dI_{d}/dt of the change over time of the value of the drain current I_{d} increases, and the length of the period in which the drain current I_{d} changes becomes longer as the absolute value of the gradient dI_{d}/dt of the change over time of the value of the drain current I_{d} decreases. Accordingly, by classifying the sampling data Sd into a plurality of classifications CL according to the gradient dI_{d}/dt and determining the sampling data Sd using the electrical standard based on each classification CL, it is possible to determine whether the sampling data Sd satisfies the electrical standard according to a time at which a pulse is applied to the transistor 50. As a result, it is possible to appropriately perform determination of the inspection data group DG with higher accuracy.

According to the embodiment, the standard calculating circuitry 13 calculates the electrical standard on the basis of a rated value of current of the transistor 50, a rated value of voltage of the transistor 50, a maximum value of an on-resistance of the transistor 50, a permissible loss P_{d} of the transistor 50, and the value of current and the value of voltage associated with a secondary breakdown of the transistor 50. Accordingly, it is possible to appropriately cause the standard calculating circuitry 13 to easily calculate the safe operating area 70S as the electrical standard.

According to the embodiment, the standard calculating circuitry 13 adjusts the electrical standard on the basis of the case temperature T_{c} as the temperature of the transistor 50. Accordingly, for example, when the temperature of the transistor 50 is predicted to be higher than that in a normal state while the circuit 40 is operating, it is possible to adjust the electrical standard according to the predicted temperature, that is, to perform temperature derating, by inputting the predicted temperature to the inspection device 100. As a result, it is possible to perform operation inspection of the circuit 40 including the transistor 50 with higher accuracy.

According to the embodiment, the inspection device 100 further includes a waveform generating circuitry 15 configured to generate a time waveform W of the value of current and the value of voltage in the inspection data group DG. The waveform generating circuitry 15 displays the sampling data Sd not satisfying the electrical standard in the inspection data group DG on the time waveform W. Accordingly, an operator can more appropriately ascertain what in the inspection data group DG on the time axis does not satisfy the electrical standard of the transistor 50 by watching the time waveform W displayed on the display 30.

The advantageous effects of the inspection device 100 are similarly achieved in the inspection method including the methods corresponding to the constituents of the inspection device 100.

The inspection device according to at least one embodiment described above is an inspection device for performing operation inspection of a circuit including a transistor. The inspection device includes: a standard calculating circuitry configured to calculate an electrical standard of the transistor on the basis of information on specifications of the transistor; and a standard determining circuitry configured to determine whether an inspection data group including temporal data of a value of current flowing in the transistor in a predetermined time range and a value of voltage applied to the transistor satisfies the electrical standard and to output data which is determined not to satisfy the electrical standard in the inspection data group. Accordingly, it is possible to decrease a workload required for the operation inspection while securing the accuracy of the operation inspection of the circuit including the transistor.

The configuration of the standard calculating circuitry is not particularly limited as long as it can calculate an electrical standard of a transistor on the basis of information on specifications of the transistor. The electrical standard may be a standard outside of the safe operating area as long as the standard can inspect an operation of a circuit including a transistor. The standard calculating circuitry may calculate the electrical standard of the transistor on the basis of the information on the specifications of the transistor using a method not described in the embodiment. The standard calculating circuitry may calculate the electrical standard without using one or more of the rated value of current of the transistor, the rated value of voltage of the transistor, the maximum value of the on-resistance of the transistor, the permissible loss of the transistor, and the value of current and the value of voltage associated with the secondary breakdown of the transistor.

The data determining circuitry may calculate the gradient of the change over time of the value of voltage in the inspection data group and determine to what classification of a plurality of classifications each piece of data corresponds. The number of classifications which are classified on the basis of the magnitude of the gradient of the change over time of the value of current or the value of voltage is not particularly limited as long as it is equal to or greater than 2. The plurality of classifications may be classified on the basis of the magnitude of the gradient of the change over time of the value of current or the value of voltage and a length of a period in which the magnitude of the gradient is continuously held. For example, when the transistor is turned on, the magnitude of the gradient is a value closer to almost zero. However, when the length of the period in which the gradient is continuously held is short to a certain extent, the classifications may be determined with the period in which the transistor is in the ON state as a period corresponding to a case in which a pulse current flows in the transistor. The plurality of classifications may not be provided. The waveform generating circuitry may generate the time waveform of only one of the value of current and the value of voltage in the inspection data group. A method which is used for the waveform generating circuitry to display data not satisfying the electrical standard on the time waveform is not particularly limited.

The inspection device may not include the storage. In this case, the inspection device may read the information on the specifications of the transistor and the inspection data group from a storage of a server or the like installed separately from the inspection device through network communication or the like. The type of a transistor of which an operation is inspected by the inspection device and the inspection method according to the embodiment is not particularly limited. The transistor may be a transistor such as a bipolar transistor other than a field effect transistor.

The functionality of the elements disclosed herein may be implemented using circuitry or processing circuitry which includes general purpose processors, special purpose processors, integrated circuits, ASICs (“Application Specific Integrated Circuits”), FPGAs (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality.

There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An inspection device for performing operation inspection of a circuit including a transistor, the inspection device comprising:
a standard calculating circuitry configured to calculate an electrical standard of the transistor on the basis of information on specifications of the transistor; and
a standard determining circuitry configured to determine whether an inspection data group including temporal data of a value of current flowing in the transistor in a predetermined time range and of a value of voltage applied to the transistor satisfies the electrical standard and to output data which is determined not to satisfy the electrical standard in the inspection data group.

2. The inspection device according to claim 1, further comprising:
a data determining circuitry configured to calculate a gradient of a change over time of the value of current or the value of voltage in the inspection data group and to determine to which of a plurality of classifications which are classified on the basis of a magnitude of the gradient data included in the inspection data group corresponds,
wherein the standard calculating circuitry is configured to calculate, for each of the plurality of classifications, the electrical standard, and
wherein the standard determining circuitry is configured to change the electrical standard which is to be automatically used for determination of the inspection data group in accordance with the classification determined by the data determining circuitry.

3. The inspection device according to claim 1, wherein the standard calculating circuitry is configured to calculate the electrical standard on the basis of at least one of a rated value of current of the transistor, a rated value of voltage of the transistor, a maximum value of an on-resistance of the transistor, a permissible loss of the transistor, and the value of current and the value of voltage associated with a secondary breakdown of the transistor.

4. The inspection device according to claim 1, wherein the standard calculating circuitry is configured to adjust the electrical standard on the basis of a temperature of the transistor.

5. The inspection device according to claim 1, further comprising:
a waveform generating circuitry configured to generate a time waveform of at least one of the value of current and the value of voltage in the inspection data group,
wherein the waveform generating circuitry is configured to display the data determined not to satisfy the electrical standard in the inspection data group on the time waveform.

6. An inspection method of performing operation inspection of a circuit including a transistor, the inspection method comprising:
calculating an electrical standard of the transistor on the basis of information on specifications of the transistor;
determining whether an inspection data group including temporal data of a value of current flowing in the transistor in a predetermined time range and of a value of voltage applied to the transistor satisfies the electrical standard; and
outputting data which is determined not to satisfy the electrical standard in the inspection data group.

7. The inspection method according to claim 6, further comprising:
calculating a gradient of a change over time of the value of current or the value of voltage in the inspection data group;
determining to which of a plurality of classifications which are classified on the basis of a magnitude of the gradient data included in the inspection data group corresponds;
calculating, for each of the plurality of classifications, the electrical standard; and
changing the electrical standard which is to be automatically used for determination of the inspection data group in accordance with the classification determined.

8. The inspection method according to claim 6, further comprising:
calculating the electrical standard on the basis of at least one of a rated value of current of the transistor, a rated value of voltage of the transistor, a maximum value of an on-resistance of the transistor, a permissible loss of the transistor, and the value of current and the value of voltage associated with a secondary breakdown of the transistor.

9. The inspection method according to claim 6, further comprising:
adjusting the electrical standard on the basis of a temperature of the transistor.

10. The inspection method according to claim 6, further comprising:
generating a time waveform of at least one of the value of current and the value of voltage in the inspection data group; and
displaying the data determined not to satisfy the electrical standard in the inspection data group on the time waveform.

11. A non-transitory computer readable storage medium that stores a computer-executable program that causes, when executed by a computer, the computer to perform the inspection method, comprising:
calculating an electrical standard of the transistor on the basis of information on specifications of the transistor;
determining whether an inspection data group including temporal data of a value of current flowing in the transistor in a predetermined time range and of a value of voltage applied to the transistor satisfies the electrical standard; and
outputting data which is determined not to satisfy the electrical standard in the inspection data group.
